(19) United States
(12) Patent Application Publication
(10) Pub. No.: US 2006/0197129 A1
(43) Pub. Date: Sep. 7, 2006

(54) Buried and bulk channel finFET and method of making the same

(75) Inventor: Walter A. Wohlmuth, Portland, OR (US)

Correspondence Address: Mr. Joseph Pugh;TriQuint Semiconductor, 2300 N.E. Brookwood Parkway, Hillsboro, OR, 97124, US

(73) Assignee: TriQuint Semiconductor, Inc.

(21) Appl. No.: 11/073,330

(22) Filed: Mar. 3, 2005

(51) Int. Cl. H01L 29/94

(52) U.S. Cl. 257/296

(57) ABSTRACT

One embodiment of a fin-field effect transistor includes a material stack including a non-inverting su surface channel, a fin of semiconductor material positioned on the material stack, the fin including first and second opposing side surfaces, and a gate electrode positioned on the first and second opposing side surfaces of the fin.

### BACKGROUND

Integrated circuits (ICs) may include semiconductor field effect transistors (FETs). The speed and reliability at which these transistors function may determine the speed and reliability of the integrated circuit. A majority of current Silicon transistor technology makes use of the interface between a semiconductor body and an overlying dielectric layer to create a channel region within the FET controlled by a metallic contact placed on top of the dielectric. These transistors are called MISFET (metal-insulator-semiconductor FETs). The surface of the semiconducting body may be inverted by the application of a voltage across the dielectric. The inverted surface forms a well that is bounded by the non-inverted semiconductor body and the dielectric material. This surface region has excellent carrier confinement, high speed, good carrier mobility and velocity, and good on-to-off current ratios. Because these transistors have the channel at the semiconductor body-dielectric interface they are very sensitive to the properties of the interface.

The interface between Silicon and Silicon Dioxide is of very high quality, stability, and reliability. Oxide-based dielectric materials are typically used in silicon inverted surface channel transistors and these devices, which are a subset of MISFETs are termed MOSFETs (metal-oxide-semiconductor FETs). As the gate length and the Silicon Dioxide dielectric thickness is reduced within MOSFET technology to obtain high speeds, due primarily to less transit time for carrier movement, the thickness of the Silicon Dioxide layer approaches its limit for uniform growth across a wafer substrate. Additionally, as the Silicon Dioxide dielectric thickness is reduced, the tunneling current through the dielectric increases, degrading the on-to-off current ratios. This necessitates a move towards higher dielectric constant materials that have poorer interface properties with Silicon. The use of higher dielectric constant materials enables the dielectric thickness to be increased, while maintaining a given device speed.

Application of current processing methods to material systems such as Germanium, Silicon-Germanium, Indium Antimonide, Indium Arsenide, Gallium Antimonide, Indium Phosphide, Gallium Nitride, and Gallium Phosphide is possible but is very limited due to the inability to achieve good quality dielectric-to-semiconductor interfaces. Crystallographic surface terminations, surface reconstruction, surface stoichiometry, dielectric fixed and mobile charge, dielectric traps, surface states, piezoelectric induced effects, and the like, are factors that affect the semiconductor to dielectric interface quality. The limitations of interface quality in these non-Silicon based material systems may necessitate the use of alternate transistor designs.

Accordingly, it may be desirable to produce transistors having improved speed and reliability, and that may be manufactured within the constraints of the properties of readily available processing materials.

### BRIEF DESCRIPTION OF THE DRAWINGS

FIGS. 1A-1D are a schematic perspective view, a schematic cross-sectional side sectional view taken along line B-B of FIG. 1A, and a schematic cross-sectional side view taken along line C-C of FIG. 1A respectively, of one embodiment of a buried channel finFET. FIG. 1D is a schematic cross-section side view, similar to the schematic cross-section side view taken along line B-B of FIG. 1A but for a conventional buried channel transistor that does not use a fin.

FIGS. 2A-2C are schematic cross-sectional side views taken along a line similar to line B-B of FIG. 1A of three other embodiments of a buried channel finFET.

FIGS. 3A-3D are a schematic perspective view, a schematic cross-sectional side sectional view taken along line B-B of FIG. 3A, and a schematic cross-sectional side view taken along line C-C of FIG. 3A respectively, of one embodiment of a bulk channel finFET. FIG. 3D is a schematic cross-section side view, similar to the schematic cross-section side view taken along line B-B of FIG. 3A but for a conventional bulk channel transistor that does not use a fin.

FIGS. 4A-4C are schematic cross-sectional side views taken along a line similar to a line B-B of FIG. 3A of three other embodiments of a bulk channel finFET.

FIGS. 5-15 show schematic cross-sectional side views of process steps of forming one embodiment of a finFET.

FIGS. 16-20 show schematic cross-sectional side views of process steps of forming other embodiments of a finFET.

### DETAILED DESCRIPTION OF THE DRAWINGS

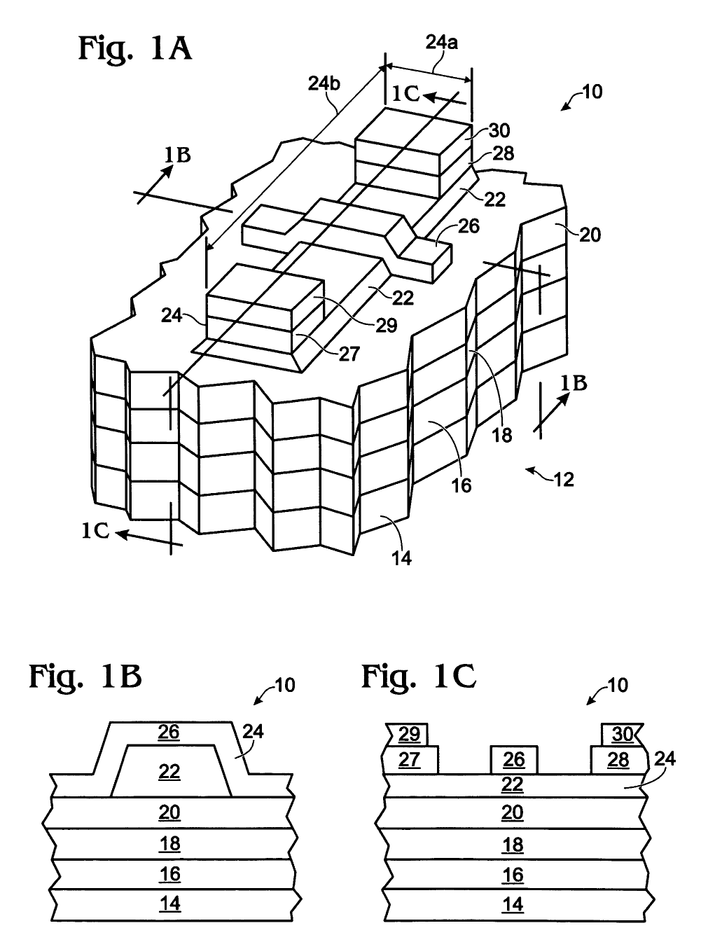

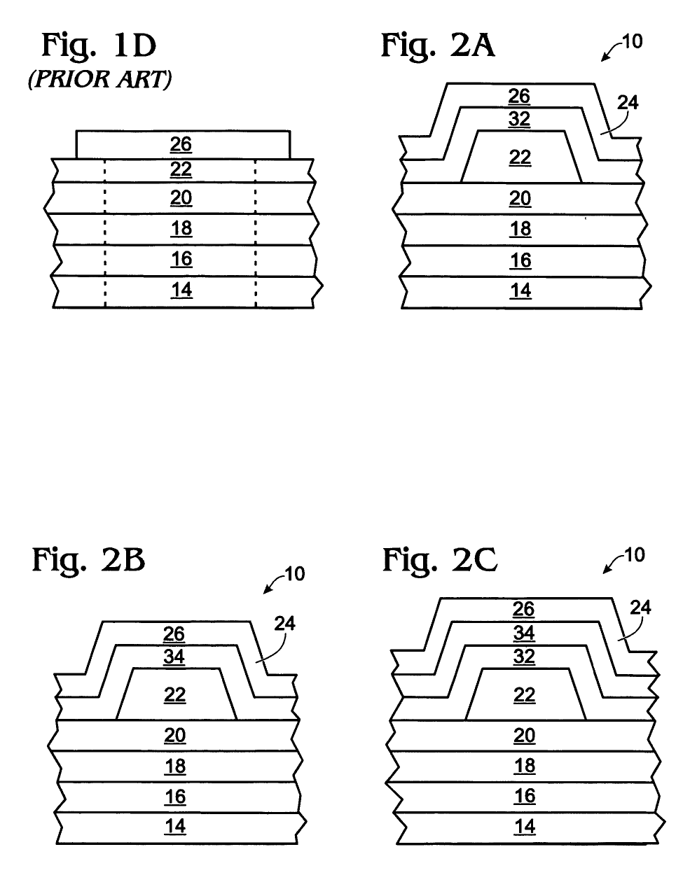

FIG. 1A is schematic perspective view of one embodiment of a buried channel finFET 10. The finFET of the present invention differs from prior art FET devices in that the channel is buried, instead of utilizing an inverting surface channel at the interface of the semiconductor body and the gate dielectric.

Semiconductor field effect transistors, or FETs, may include three terminals: a source, a drain, and a gate. When a threshold voltage is applied to the gate, a “field effect” takes place in a region of semiconductor material under the gate, called the “gate region.” The effect is either a build up of charge or a depletion of charge in the gate region. The event that occurs depends on the doping conductivity type of the gate region and the polarity of the gate voltage. The build up or depletion of charges creates a channel under the gate that electrically connects the source and the drain. If a channel is present while the drain region is biased with a voltage, and the source region is grounded relative to the drain region, then a current will flow through the channel between the drain and source regions.

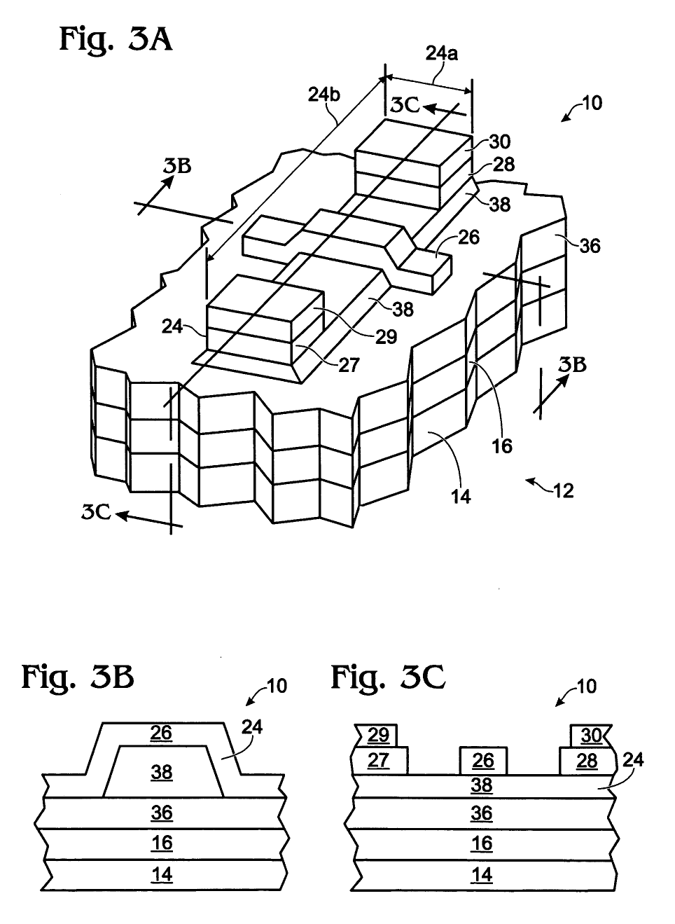

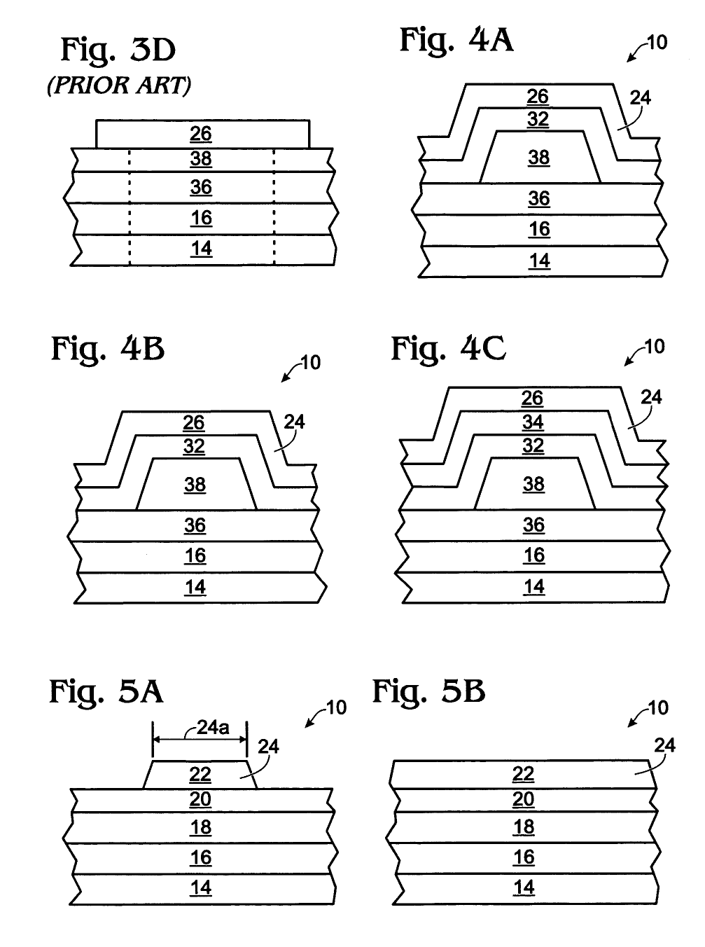

Conventional transistors have a gate electrode placed on top of only one side of the semiconductor body as shown in FIGS. 1D and 3D for the buried and bulk channel transistor, respectively. The channel width is typically defined by performing an isolation implant to damage the semiconductor body and make the isolation implant region non-conductive. The isolation implant region is not sharply defined, there is a lateral spread associated with the implant. The region with the lateral spread of damage has degraded on-to-off current ratios and therefore as the transistor width is reduced the lateral implant spread becomes more influential on the on-to-off current ratios. The present invention facilitates the creation of transistors with good on-to-off current ratios even as the transistor length is reduced. The channel length is defined by the depletion afforded by the gate electrode on the sides of the fin as shown in FIG. 1B.

The invention provides higher speed transistors than Silicon inverted surface channel based transistors given a similar gate length. The higher mobility and velocity of carriers in transistors of the present design provides this performance enhancement. The invention can be applied to Silicon-based MOSFET devices as well as GaAs, InP, GaN, etc. FETs. In particular, transistors of the present invention may include, for example, metal-semiconductor field-effect transistors (MESFETs), MISFETs, MOSFETs, junction field-effect transistors (JFETs), planar-doped barrier field-effect transistors, pseudo-morphic high-electron mobility transistors (pHEMTs), high-electron mobility transistors (HEMTs), modulation-doped field effect transistors (MODFETs), meta-morphic high-electron mobility transistors (mHEMTs), heterojunction-insulated gate FETs (HIGFETs), and heterojunction field effect transistors (HFETs). The transistors of the present invention may have a buried channel including single- and multi-heterojunction variants of the aforementioned transistor types. Such devices can be formed of semiconductor substrate and body materials, for instance, using a GaAs-based (Gallium Arsenide) material system (GaAs, AlGaAs, InGaAs, AlAs, InGaAlAs, InGaP, InGaNP, AlGaSb, GaP, etc.), an InP-based (Indium Phosphide) material system (InP, InAlP, InGaP, InGaAs, InAlAs, InSb, InAs, etc.), a Si and Ge (Silicon and Germanium) material system (Si, Ge, SiGe, SiGeC, SiO2, SiC, sapphire, etc.), or a GaN-based (Gallium Nitride) material system (GaN, AlGaN, InGaN, InAlGaN, SiC, Si, sapphire, etc.), among other possibilities. Such devices can be formed of dielectric overlying materials, for instance, using the oxides of Silicon (such as SiO2), the nitrides of Silicon (such as Si3N4), the oxides of Tantalum (such as Ta2O5), the oxides of Titanium (such as TiO2), the oxides of Hafnium (such as HfO2), the oxides of Zirconium (such as ZrO2), the oxides of Aluminum (such as Al₂O₃), perovskites, or other dielectric materials such as PZT and BST.

Among the various types of FETs are enhancement mode (E-mode) and depletion mode (D-mode) transistors. An E-mode transistor is non-conductive when the gate voltage is zero or negative. For this reason, an E-mode transistor is classified as a “normally off” transistor. An E-mode transistor is driven into conduction by bringing the gate voltage positive with respect to the source voltage. In a D-mode transistor, by contrast, there is conduction even with zero gate voltage, provided that the drain region is biased with a voltage, and the source region is grounded relative to the drain region. For this reason, D-mode transistors are classified as “normally-on” transistors. A D-mode transistor is made non-conductive by bringing the gate voltage negative with respect to the source voltage.

Referring still to FIG. 1A, in one embodiment, FET 10 may include a layered structure or stack 12 including a substrate 14, a buffer layer 16, a buried channel layer 18, a first barrier layer 20, a second barrier layer 22 in the form of a fin 24, and a gate electrode 26 that may be positioned substantially perpendicular to fin 24. Two ohmic contacts 28 and 30, with two underlying ohmic contact layers 27 and 29, may be positioned on opposite ends of fin 24. Substrate 14 may be manufactured of GaAs. Buffer layer 16 may be manufactured of GaAs and/or an Al(x)Ga(1-x)As superlattice. Buried channel 18 may be manufactured of In(y)Ga(1-y)As. First barrier layer 20 may be manufactured of Al(x)Ga(1-x)As. Second barrier layer 22, in the form of fin 24, may be manufactured of Al(x)Ga(1-x)As. Gate electrode 26 may be manufactured of TiPtAu. Ohmic contacts 28 and 30 may be manufactured of AuGeNiAu.

Accordingly, the present invention creates a fin 24 out of the semiconductor body by placing the gate contact 26 on multiple sides of the fin 24. The buried channel device displayed in FIG. 1A has the buried channel 18 positioned below the fin structure 24 with the barrier layer 20 and 22 split into two separate parts. Alternatively, the buried channel may be included within the fin structure with a single barrier layer included within the initial epitaxy growth. This structure differs from surface channel transistors because the channel of the present invention is formed within a buried layer contained within the bulk of the semiconductor body. The device may utilize biasing to deplete the semiconductor body and channel whereas a surface channel device may require biasing to invert the surface region.

To function properly the semiconductor body should be non-conductive in regions outside of the fin structure 24 such that carrier transport is confined to within the fin 24 or in the layers underneath the fin. The non-conductive properties can be provided through ion implantation damage, plasma-induced damage, etch removal of conductive layers, depletion due to surface effects, or depletion due to voltage applied to field plates contained within the overlying dielectric. The depletion of the surface region along the width 24b of the fin 24 must be closely monitored to ensure that conduction between the gate 26 and the ohmic contacts 28 and 30 is permitted.

The buried channel device is grown by epitaxy deposition techniques. The buffer layer 16 is grown on top of the substrate 14. The buried channel layer 18 is grown on top of the buffer layer 16. The channel incorporates a low bandgap semiconductor material with excellent low- and high-field carrier mobility and velocity characteristics. The low bandgap material is typically unintentionally doped to limit carrier scattering degrading mobility and velocity. The low bandgap material is bounded on top and/or bottom by a high bandgap material forming a single or double heterojunction providing good carrier confinement. The high bandgap material in close proximity to the channel is also typically unintentionally doped to limit carrier scattering. The wave functions of the carriers within the low bandgap material penetrate a distance into the high bandgap material and therefore the high bandgap material can also influence scattering events and degrade device performance. Interface quality between epitaxy layers is of paramount concern, however due to modern epitaxy growth equipment very good interface quality can be achieved.

Barrier layer 22 is grown over top the channel layer 18 and barrier layer 20. Ohmic contact layers 27 and 29 are typically grown via epitaxy on top of barrier layer 22. These layers 27 and 29 are typically highly doped to form low loss ohmic contacts and may be manufactured of GaAs and/or In(y)Ga(1-y)As. The contact layers 27 and 29 are typically raised above the barrier layers 20 and 22. The contact layers 27 and 29 can be grown in the same growth sequence as the rest of the epitaxy layers or they can be formed in a separate growth sequence—an overgrowth. Ion implantation and activation processes may be avoided in buried channel devices since the temperature required for dopant activation may result in broadening of the channel, resulting in poorer carrier confinement, poorer mobility and velocity profiles of the charge carriers, poorer on-to-off current rations, and poorer turn-off characteristics.

FIG. 1A is a schematic perspective view of one embodiment of a buried channel finFET 10. FET 10 may include a layered structure 12 including substrate 14, a buffer layer 16, a buried channel layer 18, a first barrier layer 20, a second barrier layer 22 in the form of a fin 24, and a gate electrode 26 that may be positioned substantially perpendicular to fin 24. Two ohmic contacts 28 and 30, with two underlying ohmic contact layers 27 and 29, may be positioned on opposite ends of fin 24. Buried channel layer 18 may be manufactured of In(y)Ga(1-y)As. First barrier layer 20 may be manufactured of Al(x)Ga(1-x)As. Second barrier layer 20 may be manufactured of Al(x)Ga(1-x)As.

FIGS. 1B and 1C are a schematic-cross sectional side view taken along line B-B of FIG. 1A, and a schematic cross-sectional side view taken along line C-C of FIG. 1A, respectively.

FIG. 1D is a schematic cross-section side view, similar to the schematic cross-section side view taken along line B-B of FIG. 1A but for a conventional buried channel transistor that does not use a fin.

FIGS. 2A-2C are schematic cross-sectional side views taken along a line similar to line B-B of FIG. 1A of three other embodiments of a buried channel finFET. FIG. 2A shows FET 10 including substrate 14, buffer layer 16, buried channel layer 18, first barrier layer 20, second barrier layer 22, an overgrown barrier layer 32, and gate electrode layer 26. FIG. 2B shows FET 10 including substrate 14, buffer layer 16, buried channel layer 18, first barrier layer 20, second barrier layer 22, a gate dielectric layer 34, and gate electrode layer 26. FIG. 2C shows FET 10 including substrate 14, buffer layer 16, buried channel layer 18, first barrier layer 20, second barrier layer 22, overgrown barrier layer 32, gate dielectric layer 34, and gate electrode layer 26. Overgrown barrier layer 32 may be manufactured of Al(x)Ga(1-x)As. Gate dielectric layer 34 may be manufactured of the oxides of Gd, As, and/or Ga or the sulfides of Ga.

FIG. 3A is a schematic perspective view of one embodiment of a bulk channel finFET 10. FET 10 may include a layered structure 12 including substrate 14, a buffer layer 16, a first bulk channel layer 36, a second bulk channel layer 38 in the form of a fin 24, and a gate electrode 26 that may be positioned substantially perpendicular to fin 24. Two ohmic contacts 28 and 30, with two underlying ohmic contact layers 27 and 29, may be positioned on opposite ends of fin 24. First bulk channel layer 36 may be manufactured of GaAs. Second bulk channel layer 38 may be manufactured of GaAs.

The bulk channel device utilizes a substrate material within which bulk channel layers 36 and/or 38 can be formed through ion implantation and subsequent carrier activation through annealing processes. The ohmic contact layers 27 and 29 can also be formed through ion implantation and activation processes.

Alternatively, the bulk channel layers 36 and/or 38 can be formed via epitaxy growth. In one preferred embodiment the substrate 14 may be manufactured of Si, the buffer layer 16 may be manufactured of the binary compound GaP or ternary and quaternary compounds thereof an d the bulk channel layers 36 and/or 38 may be manufactured of the binary compound InAs or ternary and quaternary compounds thereof.

FIGS. 3B and 3C are a schematic cross-sectional side view taken along line B-B of FIG. 3A, and a schematic cross-sectional side view taken along line C-C of FIG. 3A, respectively.

FIG. 3D is a schematic cross-section side view, similar to the schematic cross-section side view taken along line B-B of FIG. 3A but for a conventional bulk channel transistor that does not use a fin.

FIGS. 4A-4C are schematic cross-sectional side views taken along a line similar to line B-B of FIG. 4A of three other embodiments of a bulk channel finFET 10. FIG. 4A shows FET 10 including substrate 14, buffer layer 16, first bulk channel layer 36, second bulk channel layer 38, overgrown barrier layer 32, and gate electrode layer 26. FIG. 4B shows FET 10 including substrate 14, buffer layer 16, first bulk channel layer 36, second bulk channel layer 38, gate dielectric layer 34, and gate electrode layer 26. FIG. 4C shows FET 10 including substrate 14, buffer layer 16, first bulk channel layer 36, second bulk channel layer 38, overgrown barrier layer 32, gate dielectric layer 34, and gate electrode layer 26.

FIGS. 5-15 are schematic cross-sectional side views of the process of forming one embodiment of buried channel FET 10 outlined in FIG. 1A. FIGS. 5A and 5B show fin delineation on a substrate 14 and then sequentially depositing buffer layer 16, buried channel layer 18, first barrier layer 20, and second barrier layer 22. A photoresist mask (not shown) is used to define the location of the fin structure and then an etch process and photoresist removal is used to delineate the feature.

To create fin 24, a dielectric mask may be utilized that may contain patterns defining the locations where fin 24, or fins 24, will be formed. The dielectric mask is formed by a blanket dielectric deposition, then a photoresist mask (not shown) patterning and finally a dielectric etch and photoresist removal. The fin or fins may then be deposited, using epitaxy overgrowth technique, within the patterned locations of the dielectric mask. In the embodiment shown, fin 24 may comprise second barrier layer 22.

In particular, to form fin 24, the semiconductor body may be etched using either wet or dry etch techniques. A multitude of dry etch techniques and wet etch chemistries can be used depending on the material system chosen. In the preferred approach a highly selective etch is used for precise depth control. An epitaxy etch stop layer (not shown) is typically used in this case. The etch proceeds vertically through the epitaxy until the etch stop layer (not shown) is reached at which point the vertical etch rate is greatly reduced. The lateral etch rate may continue on once the etch stop is reached. A length 24a of fin 24 can be tailored by controlling the amount of lateral over-etch. Finer pitch geometries than that which was printed within the photoresist mask using lithographic printing tools can be realized by lateral over etching. The etch stop layer can be left intact or removed. For the embodiment of a buried channel device as shown in FIG. 1A, a preferred method includes the buried channel within the fin and not underneath the fin structure. In another preferred embodiment, a bulk channel device, as shown in FIG. 3A, may use epitaxy growth to form the bulk channel. Additionally, the epitaxy structure may include ohmic contact layers within the growth sequence instead of forming the ohmic contact layers by performing an epitaxy overgrowth or implant and subsequent carrier activation.

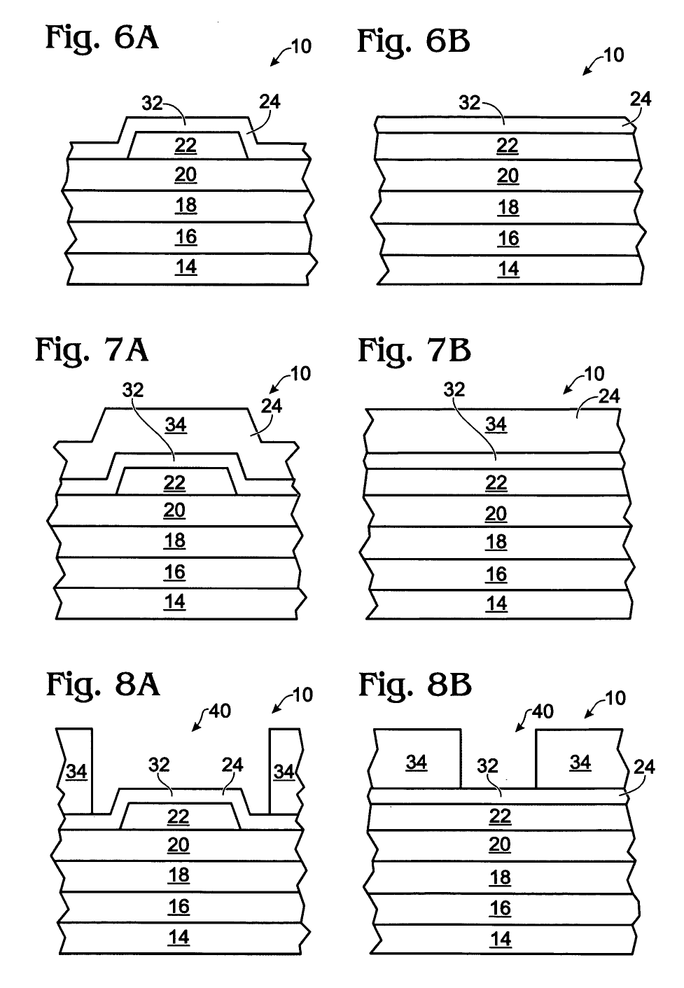

FIGS. 6A and 6B show formation of an optional epitaxy overgrown barrier layer 32.

FIGS. 7A and 7B show deposition of a conformal dielectric layer 34. Dielectric passivation of the entire wafer surface may be achieved by depositing dielectric layer 34 on fin 24, or across overgrown barrier layer 32, if present.

FIGS. 8A and 8B show formation of a dielectric opening 40 for gate placement. Opening 40 defines where the gate electrode will be positioned.

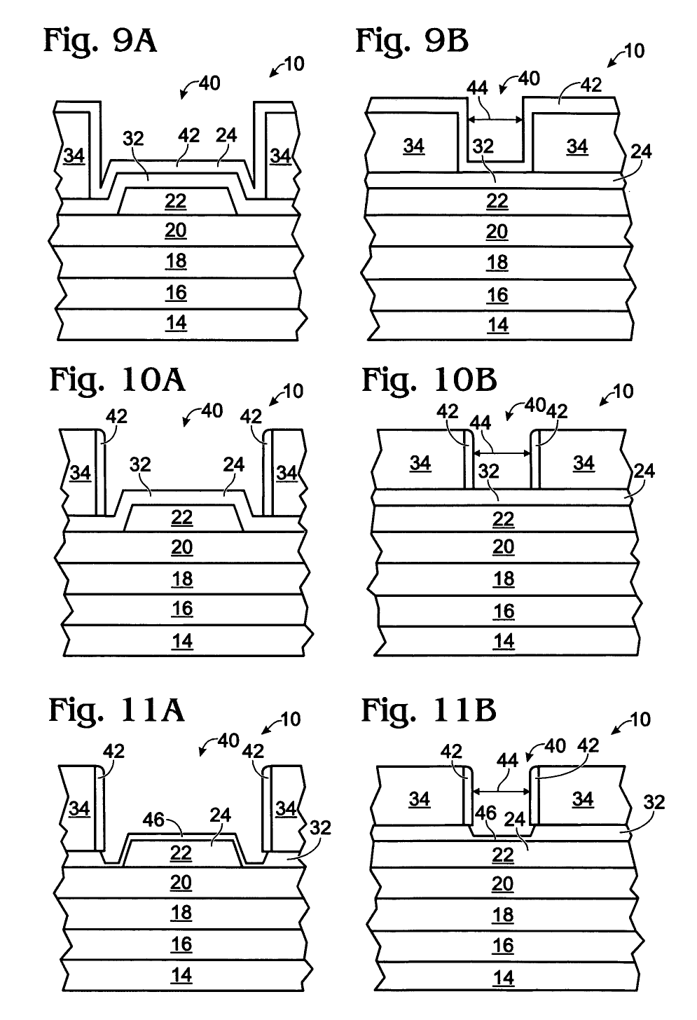

FIGS. 9A and 9B show deposition of an optional dielectric layer 42 for spacer formation. Layer 42 may also be utilized to reduce the gate feature size, or length 44, of opening 40, as shown in FIG. 9B. Reduction of length 44 of opening 40 may reduce the gate length and may enhance the operating speed of the FET. A dry etch process may be used to create opening 40 in dielectric layer 42. A blanket etch of the dielectric is performed. The change in the device from FIG. 9 to FIG. 10 may be due to the high aspect ratio of the dielectric thickness on the sidewalls 34 versus the thickness on top of layer 32. Either a wet or a dry etch may then be performed to remove the ohmic contact layers within the dielectric opening 40, if present.

FIGS. 10A and 10B show etching of optional dielectric layer 42 on fin 24. Another second optional dielectric layer 42, as shown in FIGS. 9A and 9B, may then be deposited within opening 40 to further reduce length 44 of opening 40. The steps of FIGS. 9A and 9B and 10A and 10B may be repeated numerous times to produce an opening 40 having the desired length 44. In particular, the preferred embodiment continues the processing by putting the wafer into an epitaxy growth chamber to selectively grow a barrier layer within the dielectric opening. This barrier layer covers up the exposed buried channel along the sidewalls of the fin so the channel is then confined on all four sides by a barrier layer in the buried channel transistor. The overgrowth does not occur on top of the dielectric passivation or on the sidewalls of the dielectric passivation.

FIGS. 11A and 11B show removal of a portion of overgrown barrier layer 32 to leave a partial barrier layer 46 in the region of opening 40. The amount of barrier layer 32 removed to form barrier layer 46 may be designed to target a particular current drive and/or threshold voltage for the FET.

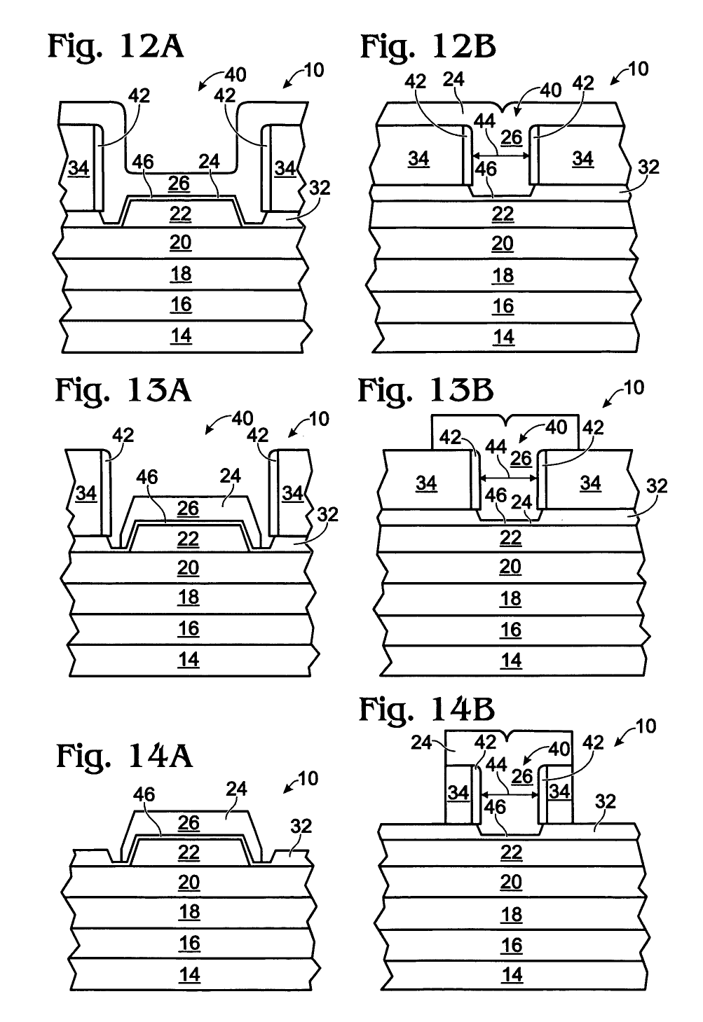

FIGS. 12A and 12B show deposition of the gate metal for gate electrode 26. Alternatively, referring to FIGS. 11A and 11B, the gate metal 26 may be formed such that the metal may diffuse and sinter or amorphize with overgrown barrier layer 32 if present or barrier layer 22 to recess the metal with barrier layer 32. In the preferred embodiment the gate metal 26 is blanket deposited on the wafer. A mask layer (not shown) is patterned within photoresist to delineate the extent of the gate feature and a metal etch back process is used to remove the gate metal in unwanted areas. Alternatively, the gate metal can be lifted off instead of etched back using the photoresist mask.

FIGS. 13A and 13B show etch back patterning of gate electrode 26.

FIGS. 14A and 14B show etch back of dielectric layer 34.

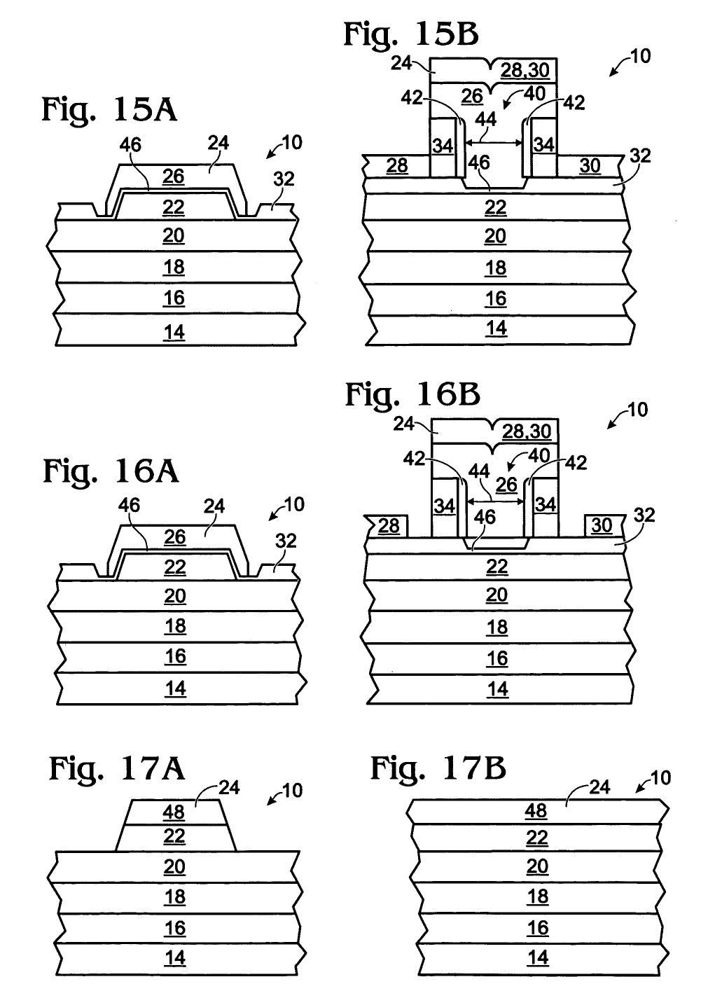

FIGS. 15A and 15B show deposition of ohmic contact 28. Ohmic contact 28 and 30 provide the source and drain electrodes for the FET. The ohmic features can be self-aligned through the use of the dielectric spacers or non-self-aligned. This embodiment is an example of a self-aligned FET. The ohmic contacts can be formed prior to the gate contact in the non-self-aligned approach.

Another photoresist mask is used to delineate the ohmic contact features. A dielectric etch is performed to open up the ohmic contact regions prior to the deposition of the ohmic contact material. A blanket deposition of ohmic metal is performed and then the metal is etched back with another photoresist mask that defined the extent of the ohmic metal. Alternatively, the ohmic metal can be deposited within the resist opening and lifted off. Upon completion of the ohmic and gate contact the entire wafer is passivated with dielectric to enclose the ohmic and gate contacts. The processing of the device continues with the formation of the interconnect stack and passive components embedded within this stack.

FIG. 16 shows another embodiment wherein ohmic contact 28 and 30 is pulled back from the gate electrode region. This embodiment is an example of a non-self aligned gate electrode.

In another embodiment, the epitaxy structure does not include ohmic contact layers 27 and 29 within the epitaxy growth sequence. The growth is halted after the formation of the barrier layers in the case of a buried channel device or after the formation of the bulk channel in the bulk channel device. Upon completion of the gate contact a dielectric passivation layer is deposited over the entire wafer and openings are formed within this layer in areas where the ohmic contact layers will reside. The ohmic contact layers are then overgrown in an epitaxy chamber. Subsequently the ohmic contact metal is delineated on top of the overgrown ohmic contact layers. The overgrown ohmic contact layers and/or the ohmic contacts 28 and 30 can be either self-aligned or non-self-aligned in this approach.

FIGS. 17A and 17B show another embodiment of fin 24 shown in FIGS. 5A and 5B, including incorporation of an ohmic contact layer 48 on second barrier layer 22 within fin 24 within the epitaxy growth sequence. The process steps shown in FIGS. 7-10 would remain the same, except layer 22 in those figures would be replaced by the layer 48/layer 22 fin shown in FIGS. 17A and 17B and except that barrier layer 32 of FIGS. 6A and 6B may not be deposited.

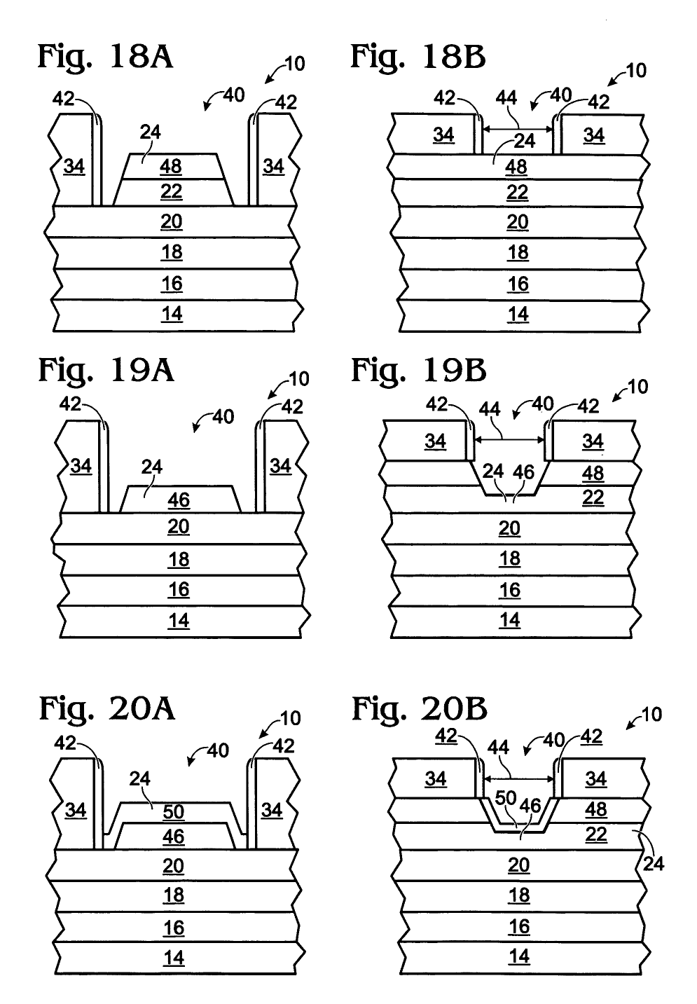

FIGS. 18A and 18B show the embodiment of FIGS. 17A and 17B, subjected to the process step shown in FIGS. 10A and 10B. In this embodiment, partial barrier layer 46 extends through ohmic contact layer 48 and barrier layer 22.

FIGS. 19A and 19B show the embodiment of FIGS. 18A and 18B, subjected to the process step shown in FIGS. 11A and 11B.

FIGS. 20A and 20B show the embodiment of FIGS. 19A and 19B wh erein a barrier overgrowth layer 50 is deposited on partial barrier layer 46. The process steps shown in FIGS. 12-15 would remain the same after deposition of layer 50.

Other alternative methods or devices may include the following. The etch of the fin can be terminated prior to exposing the buried channel within the barrier layer. Therefore, in such an embodiment, the sidewall of the fin will not expose the buried channel region. The etch of the fin can be terminated within the buffer layer in the case of either the buried channel or bulk channel devices. The etch of the fin can be terminated within the substrate layer in the case of either the buried channel or bulk channel devices. In certain embodiments, the use of an overgrown barrier layer can be used or can be neglected, as may be appropriate for a particular application. In still other embodiments, the use of a Schottky barrier contact to the semiconductor can be used. A gate metallurgy can be chosen for the Schottky barrier contact such that the material may sinter or amorphize into the semiconductor body, further shrinking the barrier layer thickness. The transistor may have a gate oxide sandwiched in between the gate metal and the semiconductor body forming a MOSFET device. The gate electrode may be biased such that the MOSFET is operated as a field effect depletion device instead of an inversion device.

Other variations and modifications of the concepts described herein may be utilized and fall within the scope of the claims below.

We claim:

1. A fin-field effect transistor, comprising:
a material stack including a non-inverting surface channel;
a fin of semiconductor material positioned on said material stack, said fin including first and second opposing side surfaces; and
a gate electrode positioned on said first and second opposing side surfaces of said fin.

2. The transistor of claim 1 wherein said channel includes at least one buried channel.

3. The transistor of claim 1 wherein said channel is a bulk channel.

4. The transistor of claim 1 wherein said fin includes a top surface, and wherein said gate electrode is positioned on said top surface.

5. The transistor of claim 1 wherein said transistor is non-inverting.

6. The transistor of claim 1 wherein said channel is operated by changing the degree of depletion.

7. The transistor of claim 1 wherein the device is self-aligned.

8. The transistor of claim 1 wherein the device is non-self-aligned.

9. The transistor of claim 1 wherein said semiconductor material is chosen from one of or a composite of Gallium, Arsenide, Aluminum, Indium, Phosphorous, Nitrogen, Antimony, GaAs, AlGaAs, InGaAs, AlAs, InGaAlAs, InGaP, InGaNP, AlGaSb, InSb, GaP, AlSb, GaSb, AlP, AlAs, and binary, ternary and quaternary combinations thereof, and wherein said substrate is chosen from one of Si, SiC, SiO2, sapphire, GaAs, and Ge.

10. The transistor of claim 1 wherein said semiconductor material is chosen from one of or a composite of Indium, Phosphorous, Aluminum, Antimony, InP, InAlP, InGaP, InGaAs, InAlAs, InSb, InAs, AlSb, GaSb, AlP, AlAs, and binary, ternary and quaternary combinations thereof, and wherein said substrate is chosen from one of GaAs, InP, Si, SiC, SiO2, and sapphire.

11. The transistor of claim 1 wherein said semiconductor material is chosen from one of or a composite of Silicon, Germanium, Carbon, Oxygen, SiGe, SiGeC, SiO2, SiC, sapphire, and binary, ternary and quaternary combinations thereof, and wherein said substrate is chosen from one of Si, SiC, sapphire, and SiO2.

12. The transistor of claim 1 wherein said semiconductor material is chosen from one of or a composite of Gallium, Nitrogen, Aluminum, Indium, Silicon, Carbon, Germanium, GaN, AlGaN, InGaN, InN, AlN, InAlGaN, SiC, SiGeC, Si, sapphire, and binary, ternary and quaternary combinations thereof, and wherein said substrate is chosen from one of Si, SiC, sapphire, and SiO2.

13. The transistor of claim 1 wherein said transistor is a depletion-mode (D-mode) FET.

14. The transistor of claim 1 wherein said transistor is an enhancement-mode (E-mode) FET.

15. The transistor of claim 1 wherein said transistor comprises three terminals, including a source, a drain, and a gate electrode.

16. The transistor of claim 1 wherein said transistor comprises four terminals, including a source, a drain, a gate, and a substrate contact electrode.

17. The transistor of claim 1 wherein said transistor comprises two terminals, including a source and a drain that share a common contact, and a separate gate electrode.

18. The transistor of claim 1 wherein said transistor includes at least one sidewall spacer to reduce a gate length.

19. The transistor of claim 1 wherein said transistor includes a plurality of gate electrodes chosen from one of a dependent electrode, an independent electrode, and a combination thereof.

20. The transistor of claim 1 wherein said material stack includes a buried channel and a first barrier layer positioned thereon, and wherein said fin comprises a second barrier layer positioned on said first barrier layer.

21. The transistor of claim 1 wherein said material stack includes a bulk channel and a first barrier layer positioned thereon, and wherein said fin comprises a second barrier layer positioned on said first barrier layer.

22. The transistor of claim 1 wherein said material stack includes a substrate, a buffer layer positioned on said substrate, a buried channel layer positioned on said buffer layer and at least one barrier layer positioned on said buried channel layer, and wherein said fin terminates within one of the at least one barrier layer, the buffer layer, and the substrate.

23. The transistor of claim 22 further comprising an optional ohmic contact layer positioned on top of said at least one barrier layer, said ohmic contact layer formed during one of, during a growth sequence of said at least one barrier layer, one buried channel layer and said at least one buffer layer, and after a growth sequence of said at least one barrier layer, one buried channel layer and said at least one buffer layer as an overgrown layer.

24. The transistor of claim 21 wherein said gate electrode is positioned directly on said second barrier layer.

25. The transistor of claim 21 further comprising an overgrown barrier layer positioned on said at least one barrier layer.

26. The transistor of claim 21 further comprising a gate dielectric layer positioned on said barrier layers, and wherein said gate electrode is positioned directly on said gate dielectric layer.

27. The transistor of claim 21 further comprising an overgrown barrier layer positioned on said at least one barrier layer and a gate dielectric layer positioned on said overgrown barrier layer, and wherein said gate electrode is positioned directly on said gate dielectric layer.

28. The transistor of claim 1 wherein said material stack includes a substrate, at least one buffer layer positioned on said substrate, and at least one bulk channel layer positioned on said at least one buffer layer, and wherein said fin terminates within one of said at least one bulk channel layer, said at least one buffer layer, and said substrate.

29. The transistor of claim 28 further comprising an optional ohmic contact layer positioned on top of said at least one bulk channel layer, said ohmic contact layer formed during one of during a growth sequence of said at least one bulk channel layer and said at least one buffer layer, and after a growth sequence of said at least one bulk channel layer and said at least one buffer layer as an overgrown layer.

30. The transistor of claim 28 wherein said gate electrode is positioned directly on said bulk channel.

31. The transistor of claim 30 wherein said gate electrode is formed with the use of a gate recess.

32. The transistor of claim 30 wherein said gate electrode is formed without the use of a gate recess.

33. The transistor of claim 28 further comprising an overgrown barrier layer positioned on said bulk channel layer.

34. The transistor of claim 28 further comprising a gate dielectric layer positioned on said bulk channel layer, and wherein said gate electrode is positioned directly on said gate dielectric layer.

35. The transistor of claim 28 further comprising an overgrown barrier layer positioned on said bulk channel layer and a gate dielectric layer positioned on said overgrown barrier layer, and wherein said gate electrode is positioned directly on said gate dielectric layer.

36. The transistor of claim 1 wherein said transistor is chosen from one of a MESFET, a MISFET, a MOSFET, a JFET, a planar-doped barrier field-effect transistor, a pHEMT, a HEMT, a MODFET, a mHEMT, a HIGFET, and a HFET.

37. The transistor of claim 36 wherein said transistor is chosen from one of a single-heterojunction transistor and a multi-heterojunction transistor.

38. The transistor of claim 1 wherein said gate dielectric material is chosen from one of an oxide of Silicon, a nitride of Silicon, an oxide of Tantalum (such as Ta2O5), an oxide of Titanium, an oxide of Hafnium, an oxide of Zirconium, an oxide of Aluminum, a perovskite, PZT, and BST.

39. A multi-gate fin-field effect transistor, comprising:
a substrate stack including a channel, wherein said channel is chosen from one of a buried channel and a bulk channel;
a fin of semiconductor material positioned on said substrate stack, said fin including first and second opposing side surfaces; and
a gate electrode positioned on said first and second opposing side surfaces of said fin.

40. A multi-gate fin-field effect transistor, comprising:
a substrate stack including a non-inverting channel layer;
a fin of semiconductor material positioned on said substrate stack, said fin including first and second opposing side surfaces; and
a gate electrode positioned on said first and second opposing side surfaces of said fin.

41. A multi-gate fin-field effect transistor, comprising:
a substrate stack including a channel layer that is depleted during operation;
a fin of semiconductor material positioned on said substrate stack, said fin including first and second opposing side surfaces; and
a gate electrode positioned on said first and second opposing side surfaces of said fin.

42. A multi-gate fin-field effect transistor, comprising:
a substrate stack including a channel layer that is depleted during operation;
a fin of semiconductor material positioned on said substrate stack, said fin including first and second opposing side surfaces; and
a gate electrode positioned on said first and second opposing side surfaces of said fin.

43. The transistor of claim 21 wherein said gate electrode is formed with the use of a gate recess.

44. The transistor of claim 21 wherein said gate electrode is formed without the use of a gate recess.
